(19) United States
(12) Patent Application Publication
(10) Pub. No.: US 2025/0132147 A1
(43) Pub. Date: Apr. 24, 2025

(54) METHODS FOR TREATMENT OF HIGH-K MATERIALS TO REDUCE LEAKAGE CURRENT AND INCREASE CAPACITANCE

(71) Applicant: Applied Materials, Inc., Santa Clara, CA (US)

(72) Inventors: Jae Young PARK, Sunnyvale, CA (US); Wei LIU, San Jose, CA (US); Minghang LI, Santa Clara, CA (US); Moon Hee SEO, Santa Clara, CA (US); Dileep Venkata Sai VADLADI, Sunnyvale, CA (US); Sahil TAHILIANI, San Jose, CA (US); Sandip NIYOGI, Oakland, CA (US); Dimitrios PAVLOPOULOS, Glendale, CA (US); Amit JAIN, San Diego, CA (US); Vladimir NAGORNY, Tracy, CA (US); Victor CALDERON, Santa Clara, CA (US); Edric TONG, Sunnyvale, CA (US); Rene GEORGE, Redwood City, CA (US)

(21) Appl. No.: 18/922,507

(22) Filed: Oct. 22, 2024

Related U.S. Application Data
(60) Provisional application No. 63/592,827, filed on Oct. 24, 2023.

(51) Int. Cl. H01L 21/02; C23C 16/40; C23C 16/455; C23C 16/46; H01J 37/32

(52) U.S. Cl. CPC H01L 21/02252; C23C 16/405; C23C 16/45536; C23C 16/46; H01J 37/321; H01J 37/3244; H10D 1/692; H01J 2237/3321

(57) ABSTRACT

Implementations described herein relate to systems and methods treating high-k materials for use in forming MIM capacitors. Including various high-density plasma nitridation processes or combinations of high-density plasma oxidation processes and high-density plasma nitridation processes are provided.

### CROSS-REFERENCE TO RELATED APPLICATIONS

This application claims the benefit of U.S. Provisional Patent Application Ser. No. 63/592,827, filed Oct. 24, 2023, which is incorporated by reference herein in its entirety.

### TECHNICAL FIELD

Implementations of the present disclosure generally relate to metal-insulator-metal (“MIM”) capacitors in integrated circuits. More particularly, implementations of the present disclosure relate to methods for treating a high-k material using high density radicals.

### BACKGROUND

Capacitors are one component in semiconductor devices that can occupy considerable area on a semiconductor die depending on the size of the capacitor and/or the number of capacitors on the die. One example of a capacitor used in a semiconductor memory device is a metal-insulator-metal (MIM) capacitor. A traditional MIM capacitor is two-dimensional (2D). A 2D MIM capacitor has two facing metal plates which are planar and substantially parallel to each other and to the substrate. One method of increasing the capacitance of a MIM capacitor is to increase the sizes of the metal plates. However, increasing the sizes of the metal plates will consume more surface area of the substrate. A 3-dimensional (3D) MIM capacitor allows for the same capacitive surface area but consumes less surface area of a substrate. However, a 3D MIM capacitor can lose performance if a leakage current develops between the two metal plates.

In capacitors, a dielectric layer placed between two electrodes, is often utilized and formed to store electric charges when the display devices are in operation. It is desirable for capacitors to have a high capacitance when for use display devices. The capacitors may therefore be formed using high-k dielectric materials. When the dielectric layer is formed with a material having a high-k dielectric constant, the capacitance of the capacitor formed will increase as well. However, certain characteristics of high-k dielectric materials such as oxygen pores, grain boundaries, and impurities can increase leakage and reduce the dielectric constant.

Accordingly, there is a need for improved methods to suppress leakage current and maintain high dielectric constants in high-k materials.

### SUMMARY

Implementations of the present disclosure generally relate to metal-insulator-metal (“MIM”) capacitors in integrated circuits. More particularly, implementations of the present disclosure relate to methods for treating a high-k material using high density radicals.

In one or more implementations, of the present disclosure, a plasma processing method is provided. The method includes receiving a substrate stack into a processing chamber, the substrate stack including a high-k dielectric layer formed over a metal electrode. The method further includes introducing a process gas into a gas injection channel defined between a gas injection insert and a sidewall of a plasma source. The method further includes generating an inductively coupled plasma within the gas injection channel with an induction coil positioned proximate the sidewall and horizontally overlapping the gas injection channel. The plasma includes at least one nitrogen radical species. The method further includes delivering the plasma from the plasma source to the processing chamber coupled therewith, wherein the plasma flows through a separation grid disposed between the plasma source and the substrate stack to be processed. The method further includes processing the substrate stack within the processing chamber, wherein processing the substrate stack includes contacting the plasma including the at least one nitrogen radical species with the high-k dielectric layer facing the separation grid and heating the substrate stack using a plurality of lamps located on a second side of the substrate stack opposite the separation grid.

Implementations may include one or more of the following. Implementations may include one or more of the following. After processing the substrate stack with the plasma, the method further includes introducing an oxygen-containing gas into the gas injection channel of the plasma source; generating an oxygen plasma within the gas injection channel, wherein the oxygen plasma includes oxygen radicals; delivering the oxygen plasma from the plasma source to the processing chamber; and processing the substrate stack with the oxygen plasma within the processing chamber, wherein processing the substrate stack comprises contacting the oxygen plasma including the oxygen radicals with the high-k dielectric layer facing the separation grid; and heating the substrate stack using the plurality of lamps located on the second side of the substrate stack opposite the separation grid. Processing the substrate stack within the processing chamber forms one or more nitrogen-containing diffusion barrier layers within the substrate stack. A diffusion barrier layer of the one or more diffusion barrier layers is formed within the high-k dielectric layer. A diffusion barrier layer of the one or more diffusion barrier layer is formed at an interface of the high-k dielectric layer and the metal electrode. The high-k dielectric layer includes zirconium oxide, hafnium oxide, or a combination of zirconium oxide and hafnium oxide. The metal electrode includes a metal nitride with the metal selected from titanium (Ti), molybdenum (Mo), tungsten (W), or tantalum (Ta). The high-k dielectric layer is formed by an atomic layer deposition (ALD) process.

In one or more implementations, a plasma processing method is provided. The method includes receiving a substrate stack into a processing chamber, the substrate stack includes a high-k dielectric layer formed over a metal electrode. The method further includes introducing a process gas into a gas injection channel defined between a gas injection insert and a sidewall of a plasma source. The method further includes generating an inductively coupled plasma within the gas injection channel with an induction coil positioned proximate the sidewall and horizontally overlapping the gas injection channel, wherein the plasma includes at least one oxygen radical species. The method further includes delivering the plasma from the plasma source to the processing chamber coupled therewith, wherein the plasma flows through a separation grid disposed between the plasma source and the substrate stack to be processed. The method further includes processing the substrate stack within the processing chamber, wherein processing the substrate stack includes contacting the plasma including the at least one oxygen radical species with the high-k dielectric layer facing the separation grid; and heating the substrate stack using a plurality of lamps located on a second side of the substrate stack opposite the separation grid.

Implementations may include one or more of the following. After processing the substrate stack with the plasma, the method further includes introducing a nitrogen-containing gas into the gas injection channel of the plasma source; generating a nitrogen plasma within the gas injection channel, wherein the nitrogen plasma includes nitrogen radicals; delivering the nitrogen plasma from the plasma source to the processing chamber; and processing the substrate stack with the nitrogen plasma within the processing chamber, wherein processing the substrate stack includes: contacting the nitrogen plasma including the nitrogen radicals with the high-k dielectric layer facing the separation grid; and heating the substrate stack using the plurality of lamps located on the second side of the substrate stack opposite the separation grid. Processing the substrate stack with the nitrogen plasma forms one or more nitrogen-containing diffusion barrier layers within the substrate stack. A diffusion barrier layer of the one or more diffusion barrier layers is formed within the high-k dielectric layer. A diffusion barrier layer of the one or more diffusion barrier layer is formed at an interface of the high-k dielectric layer and the metal electrode. The high-k dielectric layer includes zirconium oxide, hafnium oxide, or a combination of zirconium oxide and hafnium oxide. The metal electrode includes a metal nitride with the metal selected from titanium (Ti), molybdenum (Mo), tungsten (W), or tantalum (Ta). The high-k dielectric layer is formed by an atomic layer deposition (ALD) process.

In one or more implementations, a plasma processing system is provided. The system includes a processing chamber defining a processing volume; a plasma source; a gas injection insert disposed within the plasma source; a gas injection channel defined between the gas injection insert and a sidewall of the plasma source; an induction coil positioned proximate to the sidewall and horizontally overlapping the gas injection channel; a separation grid that separates the plasma source from the processing volume; and a system controller. The system controller includes a memory for storing computer readable instructions and a processor coupled to the memory, the processor is configured by the computer readable instructions that when executed by the processor perform a plurality of operations. The plurality of operations include introducing a process gas into the gas injection channel; generating an inductively coupled plasma within the gas injection channel with the induction coil, wherein the plasma includes at least one nitrogen radical species; delivering the plasma from the plasma source to the processing volume, wherein the plasma flows through the separation grid; and processing a substrate stack within the processing volume, the substrate stack including a high-k dielectric layer formed over a metal electrode. Processing the substrate stack includes contacting the plasma including the at least one nitrogen radical species with the high-k dielectric layer facing the separation grid and heating the substrate stack using a plurality of lamps located on a second side of the substrate stack opposite the separation grid.

Implementations may include one or more of the following. The plurality of operations further include introducing an oxygen-containing gas into the gas injection channel of the plasma source; generating an oxygen plasma within the gas injection channel, wherein the oxygen plasma includes oxygen radicals; delivering the oxygen plasma from the plasma source to the processing volume; and processing the substrate stack with the oxygen plasma within the processing volume, wherein processing the substrate stack includes contacting the oxygen plasma including the oxygen radicals with the high-k dielectric layer facing the separation grid and heating the substrate stack using the plurality of lamps located on the second side of the substrate stack opposite the separation grid. Processing the substrate stack within the processing volume forms one or more nitrogen-containing diffusion barrier layers within the substrate stack. The high-k dielectric layer includes zirconium oxide, hafnium oxide, or a combination of zirconium oxide and hafnium oxide and the metal electrode includes a metal nitride with the metal selected from titanium (Ti), molybdenum (Mo), tungsten (W), or tantalum (Ta).

In another implementation, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, and may admit to other equally effective implementations.

FIG. 1 is a schematic view of a system in accordance with one or more implementations described herein.

FIG. 2 is a flow diagram depicting a method of treating a high-k dielectric layer in accordance with one or more implementations described herein.

FIGS. 3A-3C illustrate views of various stages of forming a semiconductor structure in accordance with one or more implementations described herein.

FIG. 4 is a flow diagram depicting a method of treating a high-k dielectric layer in accordance with one or more implementations described herein.

FIGS. 5A-5C illustrate views of various stages of forming a semiconductor structure in accordance with one or more implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Implementations described herein relate to systems and methods treating high-k materials for use in forming MIM capacitors.

During MIM capacitor formation, carbon impurities within the high-k dielectric material, oxygen vacancies, and interdiffusion of impurities between materials have been major problems that deteriorate MIM capacitor characteristics by increasing leakage current and decreasing dielectric constant. In conventional MIM capacitor formation processes, there are currently no special treatment processes for reducing oxygen vacancy in high-k materials and traps at grain boundaries due to crystallization, and only post thermal anneal was applied to increase crystallinity.

In order to dramatically improve the increase in leakage current and decrease in dielectric constant of MIM capacitors, various high-density plasma nitridation processes or combinations of high-density plasma oxidation processes and high-density plasma nitridation processes are provided. The processes described are helpful in reducing leakage current and increasing capacitance in MIM capacitors. The removal of oxygen vacancies in high-k layers, prevention of an increase in the interfacial layer thickness through the formation of nitric layers between high-k layers and electrodes, the formation of barriers to prevent inter-diffusion of impurities from high-k layers and electrodes, and the enhancement of crystallinity in high-k without post-deposition anneal.

In one or more implementations, which can be combined with other implementations, a plasma treatment process including plasma nitridation of a high-k dielectric material is provided. Applying plasma nitridation on a high-k dielectric material can (i) increase the crystallinity in the high-k dielectric material through its relatively high-temp temp, for example, with a heater temperature in a range from about 400° C. to about 600° C. and/or a relatively high temperature plasma gas; (ii) further passivate oxygen vacancies due to high density nitrogen radicals; and (iii) form a diffusion barriers against oxidant coming from subsequent deposition of high-k dielectric materials and/or subsequent thermal treatments, which may increase the k-value and further suppress leakage current. In addition, plasma nitridation at relatively high temperatures, for example, greater than 400° C. can sufficiently increase crystallinity in the high-k dielectric material, thus eliminating additional heat treatment steps previously used.

In one or more implementations, which can be combined with other implementations, a dual treatment plasma process including a plasma oxidation followed by plasma nitridation on high-k materials is provided. The dual treatment of plasma oxidation (PO) followed by plasma nitridation (PN) on a high-k dielectric material can further increase the crystallinity in high-k and further reduce leakage current compared to plasma nitridation alone. Applying plasma oxidation can (i) remove carbon impurities from the high-k dielectric material through chemical reaction between carbon and high-density oxygen radicals; and (ii) passivate oxygen vacancies with high-density oxygen radicals, which can eventually increase the k-value by increasing crystallinity in the high-k dielectric material and reduce the leakage current by removing traps. However, in order to prevent or reduce oxidation of the lower electrode, the plasma oxidation process is applied at a temperature below the high-k deposition temperature, for example, in a range from about 150° C. to about 350° C. or from about 250° C. to about 350° C. Subsequent plasma nitridation can (i) increase the crystallinity in the high-k dielectric material through the relatively high-temperature, for example, with a heater temperature in a range from about 400° C. to about 600° C. and/or relatively high temperature plasma gas; (ii) further passivate oxygen vacancies due to high density nitrogen radicals; and (iii) form diffusion barriers against oxidants from subsequent deposition of additional high-k dielectric materials and/or thermal treatments, which eventually increases the k-value and further suppress leakage current. In addition, plasma nitridation performed at relatively high temperatures, for example, 350° C. or greater, can sufficiently increase crystallinity in the high-k dielectric material, thus eliminating the additional heat treatment steps previously used.

In one or more implementations, which can be combined with other implementations, a dual treatment plasma process including a plasma nitridation followed by plasma oxidation on high-k materials is provided. Applying plasma nitridation can (i) increase the crystallinity in the high-k dielectric material through relatively high temperatures, for example, with a heater temperature at 400° C. or greater and/or a relatively high temperature plasma gas; (ii) further passivate oxygen vacancies due to high density nitrogen radicals; and (iii) form a diffusion barriers against oxidant coming from subsequent deposition of high-k dielectric materials and thermal treatments, which eventually increases the k-value and further suppresses leakage current. Additionally, applying plasma nitridation can cause further nitridation at the interface between the bottom electrode and the bulk high-k dielectric material, which may help suppress the increase in the reaction layer due to oxidation of the bottom electrode that may occur with subsequent plasma oxidation. Subsequent plasma oxidation can (i) remove carbon impurities from the high-k dielectric material through chemical reaction between carbon and the high-density oxygen radicals; and (ii) passivate oxygen vacancies with high-density oxygen radicals, which can eventually increase the k-value by increasing crystallinity in the high-k dielectric material and reduce leakage current by removing traps. However, to prevent oxidation of the lower electrode, it needs to be applied below the high-k deposition temperature, for example, in a range from about 150° C. to about 350° C. or from about 250° C. to about 350° C.

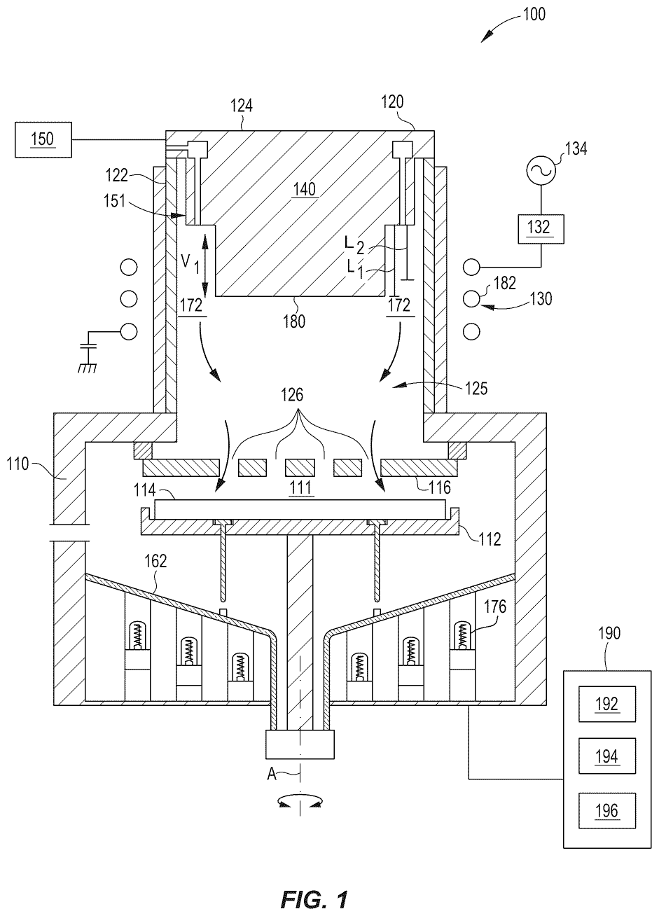

FIG. 1 is a schematic view of a plasma processing system, in accordance with one or more implementations of the present disclosure. The plasma processing system 100 includes a processing chamber 110 and a plasma source 120 (e.g., a remote plasma source) coupled with the processing chamber 110. The processing chamber 110 also includes a substrate support 112 operable to hold a substrate 114. The processing chamber 110 defines a processing volume 111 in between the plasma source 120 and the substrate support 112. Substrate support 112 can be proximate one or more heat sources (e.g., a plurality of lamps 176) that provide heat to a substrate during processing of the substrate in the processing chamber 110. The plurality of lamps 176 are disposed between the window 162 and a bottom wall of the processing chamber 110. The substrate support 112 is disposed between a separation grid 116 and the window 162.

The plasma source 120 includes a dielectric sidewall 122. The plasma source 120 includes a top cover 124. The dielectric sidewall 122 and the top cover 124, integrated with a gas injection insert 140 define a plasma source interior 125. The dielectric sidewall 122 can include any suitable dielectric material, such as quartz. An induction coil 130 is disposed proximate (e.g., adjacent) the dielectric sidewall 122 about the plasma source 120. The induction coil 130 is coupled to an RF power generator 134 through any suitable matching network 132. Feed gases are introduced to the plasma source interior 125 from a gas supply 150. When the induction coil 130 is energized with RF power from the RF power generator 134, a plasma is generated in the plasma source 120. To increase efficiency, the plasma processing system 100 includes a gas injection insert 140 disposed in the plasma source interior 125. The gas injection insert 140 includes one or more gas injection channels 151. The gas injection channels 151 provide the process gas to the plasma source interior 125 through an active zone 172, where due to enhanced confinement of hot electrons, a reaction between hot electrons and the feed gas occurs. The induction coil 130 at least partially horizontally overlaps with the gas injection channels 151.

A plasma can be generated in the plasma source 120 (e.g., in a plasma generation region) by the induction coil 130 and targeted particles flow from the plasma source 120 to the surface of the substrate 114 through holes 126 provided in a separation grid 116 that separates the plasma source 120 from the processing chamber 110 (a downstream region). The separation grid 116 is configured to separate the processing volume 111 from plasma charged particles (ions and electrons), which recombine on the separation grid 116, so that only neutral plasma species can pass through the separation grid 116 into the processing volume 111 of the processing chamber 110.

In some implementations, the induction coil 130 is aligned with the active zone 172 in such a way that a top turn of the induction coil 130 is above a bottom edge 180 or bottom surface of the gas injection insert 140 and operates substantially in the active zone 172 of the inner volume, while a bottom turn of the induction coil 130 is below the bottom edge 180 and operates substantially outside the active zone 172. A center of the induction coil 130 is substantially aligned with the bottom edge 180. Within these boundaries, the position of the induction coil 130 can be adjusted for a targeted performance.

In some implementations, the bottom edge 180 is aligned with a portion of induction coil 130 (e.g., coil loop 182) along axis 184 by utilizing a suitably sized gas injection insert 140 (and top cover 124, which may be a preformed part of the gas injection insert 140) to form the plasma source 120. Alternatively, the bottom edge 180 can be movable along a vertical direction V₁ relative to plasma source 120 while a remainder portion of the gas injection insert 140 is static (e.g., fixed) as part of plasma source 120, in order to provide alignment of the bottom edge 180 with a portion of the induction coil 130. For example, a mechanism can be coupled with any suitable portion of the gas injection insert 140 to adjust a position of the bottom edge 180 such that a portion of the gas injection insert 140 having a first length (L₁) is adjusted to a second length (L₂).

The substrate 114 may be positioned in the processing chamber directly below the separation grid 116 and some distance from the separation grid 116, and neutral particles from plasma source 120 may flow downward through the separation grid 116 toward the substrate 114 in the processing chamber 110, and the neutral particles may contact the substrate 114 to perform a process, for example, a surface treatment process.

The plasma processing system 100 further includes a system controller 190 for controlling processes performed by the plasma processing system 100. The system controller 190 can be any type of controller used in an industrial setting, such as a programmable logic controller (PLC). The system controller 190 includes a processor 192, a memory 194, and input/output (I/O) circuits 196. The system controller 190 can further include one or more of the following components (not shown), such as one or more power supplies, clocks, communication components (e.g., network interface card), and user interfaces typically found in controllers for semiconductor equipment.

The memory 194 can include non-transitory memory. The non-transitory memory can be used to store the computer readable instructions, programs and settings described below. The memory 194 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

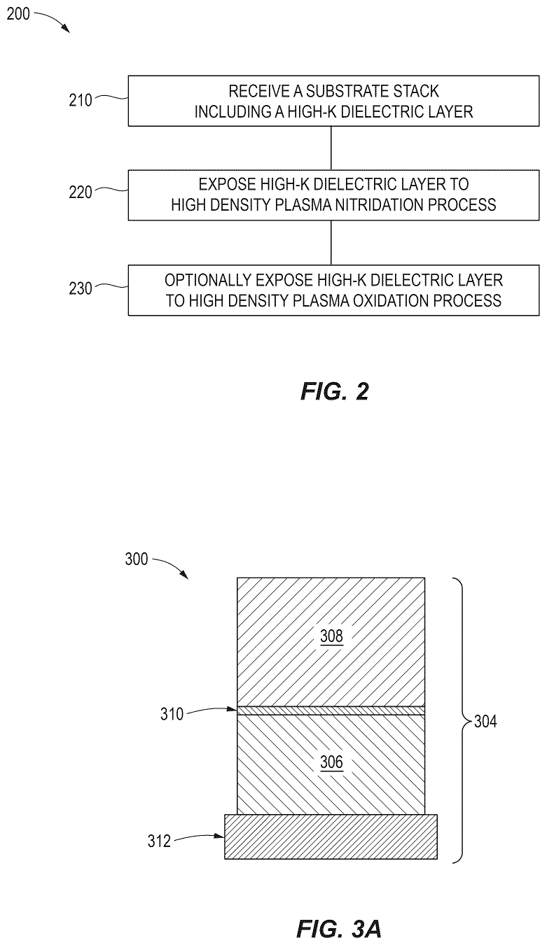

The processor 192 is coupled to the memory. The processor 192 is configured by the computer readable instructions or programs stored in the memory 194 that when executed by the processor 192 perform a plurality of operations, for example, the plurality of operations of the method 200 described in reference to FIG. 2. During execution of these instructions or programs, the system controller 190 can communicate to I/O devices through the I/O circuits 196. For example, during execution of these programs and communication through the I/O circuits 196, the system controller 190 can control outputs (e.g., the plasma source 120, the RF power generator 134, gas delivery from the gas supply 150). The memory 194 can further include various operational settings used to control the plasma processing system 100. For example, the settings can include temperature and pressure settings as well as settings to control gas delivery from the gas sources described herein.

Methods of using the plasma processing system 100 to treat a substrate using high-density radicals are provided. In certain implementations, the substrate comprises a high-k material such as a high-k dielectric material for use in forming capacitors. In some implementations, the high-k material of the substrate comprises ZrO2 or a combination of ZrO2 and HfO2.

In some implementations, the plasma processing system 100 may be used to perform a plasma nitridation process on the substrate with high-density nitrogen radicals. In some implementations, the plasma nitridation process may increase the crystallinity of the substrate and decrease oxygen vacancies. In some implementations, the plasma nitridation process may form one or more nitric layers on the substrate.

In some implementations, the plasma processing system 100 may be used to perform a plasma oxidation process on the substrate with high-density oxygen radicals. In some implementations, the plasma oxidation process may decrease impurities and oxygen vacancies in the substrate.

In some implementations, the plasma processing system 100 may be used to sequentially perform both the plasma nitridation process and the plasma oxidation process on the substrate. In certain implementations, the plasma nitridation process may be performed first followed by the plasma oxidation process. In other implementations, the plasma oxidation process may be performed first followed by the plasma nitridation process.

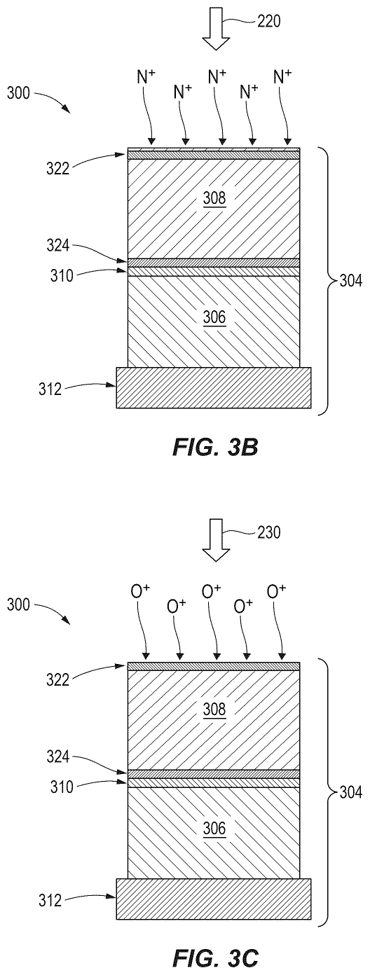

FIG. 2 is a flow diagram depicting a method 200 of treating a high-k dielectric layer in accordance with one or more implementations of the present disclosure. FIGS. 3A-3C illustrate views of various stages of forming a semiconductor structure in accordance with one or more implementations described herein. Although FIGS. 3A-3C are described in relation to the method 200, the structures disclosed in FIGS. 3A-3C are not limited to the method 200, but instead may stand alone as structures that are independent of the method 200. Similarly, although the method 200 is described in relation to FIGS. 3A-3C, the method 200 is not limited to the structures disclosed in FIGS. 3A-3C but instead may stand alone independent of the structures disclosed in FIGS. 3A-3C. It should be understood that FIGS. 3A-3C illustrate only partial schematic views of a semiconductor device structure 300, and the semiconductor device structure 300 may contain any number of transistor sections and additional materials having aspects as illustrated in the figures. The semiconductor device structure 300 can be a MIM capacitor. It should also be noted that although the method 200 illustrated in FIG. 2 is described sequentially, other process sequences that include one or more operations that have been omitted and/or added, and/or has been rearranged in another desirable order, fall within the scope of the implementations of the disclosure provided herein.

At operation 210, a substrate stack 304 is received. The substrate stack 304 may be positioned on the substrate support 112 of the plasma processing system 100 shown in FIG. 1. The substrate stack 304 may be or include the substrate 114 shown in FIG. 1. Referring to FIG. 3A, the substrate stack 304 includes a lower electrode 306 and a high-k dielectric layer 308 formed over the lower electrode 306. The substrate stack 304 may further include a substrate 312, for example a polysilicon substrate, on which the lower electrode 306 is formed.

The lower electrode 306 is or includes a metal nitride material. The lower electrode 306 can be fabricated from any suitable metal such as titanium (Ti), molybdenum (Mo), tungsten (W), or tantalum (Ta). In one or more implementations, which can be combined with other implementations, the lower electrode 306 is or includes TIN. The lower electrode 306 can be formed on the substrate 312 by any suitable process. In one or more implementations, the lower electrode 306 is formed by a physical vapor deposition (PVD) process to form the metal followed by exposure to a nitrogen plasma to form the metal nitride. The lower electrode 306 can have a thickness in a range from about 50 Angstroms to about 5,000 Angstroms.

The high-k dielectric layer 308 is formed on or over the lower electrode 306 as shown in FIG. 3A. The high-k dielectric layer 308 is fabricated from any suitable dielectric material having a k-value of 20 or higher, such as zirconium oxide (ZrO₂), aluminum oxide (Al₂O₃), titanium dioxide (TiO₂), hafnium dioxide (HfO₂), or hafnium zinc oxide (HfZO) (combination of HfO and ZrO2). In some implementations, the high-k dielectric layer 308 is a multi-layer stack including at least one layer of high-k dielectric material. In one implementation, the high-k dielectric layer 308 includes a ZrO₂ layer and a silicon nitride (SiN) layer. In another implementation, the high-k dielectric layer 308 includes a layer of high-k dielectric material sandwiched between two dielectric layers. The high-k dielectric layer 308 has a k-value ranging from about 20 to about 50. The high-k dielectric layer 308 can have a thickness greater than or equal to 50 Angstroms. The high-k dielectric layer 308 can have a thickness in a range from about 50 Angstroms to about 500 Angstroms. The high-k dielectric layer 308 can be formed on or over the substrate 312 by any suitable process. In one or more implementations, the high-k dielectric layer 308 is formed by an atomic layer deposition (ALD) process. The ALD process can be performed at a deposition temperature less than 400° C., for example, in a range from about 150° C. to about 350° C. or in a range from about 250° C. to about 350° C. The lower electrode 306 can have a thickness in a range from about 50 Angstroms to about 5,000 Angstroms.

In one or more implementations, precursors utilized for depositing the high-k dielectric layer 308 include a zirconium containing precursor and an oxygen containing precursor. Suitable zirconium containing precursor includes zirconium-organometallic precursors, such as tetrakis(ethylmethylamino)zirconium (TEMAZ), tris(dimethylamino)cyclopentadienyl zirconium (C₅H₅)Zr[N(CH₃)₂]₃, or the like. Suitable oxygen containing precursor includes H₂O, O₂, O₃, H₂O₂, CO₂, NO₂, N₂O, or the like.

The substrate stack 304 may further include a reaction layer 310 formed at the interface of the lower electrode 306 and the high-k dielectric layer 308. The reaction layer 310 may be formed by oxidation of the lower electrode 306

At operation 220, the high-k dielectric layer 308 is exposed to a high density plasma nitridation process as shown in FIG. 3B. Exposure to the high density nitridation process may form one or more nitric layers or diffusion barrier layers 322, 324 within the substrate stack 304. The diffusion barrier layers 322, 324 reduce or prevent diffusion of oxidants from subsequent deposition of additional high-k layers and/or thermal treatments in to the high-k dielectric layer 308 and the electrode 306, which can suppress an increase in the size of the reaction layer 310. In one or more implementations, a diffusion barrier layer of the diffusion barrier layers is formed at an interface of the high-k dielectric layer 308 and the lower electrode 306, for example the diffusion barrier layer 324. In one or more implementations, a diffusion barrier layer of the one or more diffusion barrier layers is formed at the upper surface of or within the high-k dielectric layer 308, for example, the diffusion barrier layer 322. The diffusion barrier layers 322, 324 can have a thickness in a range from about 5 Angstroms to about 30 Angstroms, for example, about 5 Angstroms to about 25 Angstroms, about 10 Angstroms to about 25 Angstroms, about 10 Angstroms to about 20 Angstroms, or about 10 Angstroms to about 20 Angstroms. In some implementations, the one or more diffusion barrier layers 322, 324 can be formed by exposing the high-k dielectric layer 308 to a first radical, for example, a nitrogen radical.

Referring to FIG. 1, when utilizing the plasma processing system 100 disclosed herein, a plasma including the first radical is formed in the active zone 172 of the plasma source interior 125. For example, the gas injection insert 140 can introduce a first process gas including nitrogen via the gas injection channels 151 to form the plasma including the first radical. The plasma can be an inductively coupled plasma generated within the gas injection channels 151 by the induction coil 130. The first process gas can be selected from diatomic nitrogen (N2), ammonia (NH3), or mixtures thereof. In some implementations, the first process gas can be introduced to the active zone 172 of the plasma source interior 125 at a first process gas flow rate in a range from about 1,000 standard cubic centimeters per minute (sccm) to about 10,000 sccm, for example, from about 1,000 sccm to about 9,500 sccm, from about 1,500 to about 9,500 sccm, from about 1,500 sccm to about 8,500 sccm, from about 4,000 sccm to about 8,500 sccm, or from about 6,000 sccm to about 8,000 sccm. In some implementations, the first radical can be introduced for a period of time in a range from about 10 seconds(s) to about 500 s, for example, from about 60 s to about 400 s, from about 90 s to about 300 s, or from about 120 s to about 300 s.

The plasma source 120 is configured to flow the plasma including the first radical through the holes 126 in the separation grid 116 toward the substrate support 112 to treat the substrate 114 or the substrate stack 304 disposed thereon. The plasma source 120 may generate plasma charged particles, for example, ions and electrons, which recombine on the separation grid 116, so that mostly or only neutral plasma species can pass through the separation grid 116 and expose the substrate 114 or the substrate stack 304 to the high-density nitrogen plasma. The plasma comprising the at least one nitrogen radical species contacts a side of the high-k dielectric layer 308 facing the separation grid 116. The substrate 114 or the substrate stack 304 can be heating using the plurality of lamps 176 located on a second side of the substrate stack 304 opposite the separation grid 116.

In one or more implementations which can be combined with other implementations, the high-density plasma nitridation process of operation 220 includes exposing the high-k dielectric layer 308 to an additional radical, for example, a hydroxide radical, an argon radical, a hydrogen radical, or a combination thereof. In some implementations, the additional radical can be formed in the active zone 172 of the plasma source interior 125. For example, the gas injection insert 140 can introduce an additional gas including hydrogen, argon, nitrogen, helium, or a mixture thereof into the active zone 172.

The plasma nitridation process of operation 220 may be performed while maintaining a pressure in a range from about 1 Torr to about 20 Torr, for example, from about 1 Torr to about 10 Torr, from about 1 Torr to about 8 Torr, or from about 1 Torr to about 5 Torr. In some implementations, the plasma nitridation process of operation 220 may be performed while maintaining a temperature in a range from about 400° C. to about 700° C., for example, from about 400° C. to about 650° C., or from about 550° C. to about 650° C. In some implementations, the plasma nitridation process of operation 220 may be performed while operating the plasma source at a power in a range from about 5 KW to about 10 KW, for example, from about 5 KW to about 8 KW, from about 6 KW to about 8 KW, or from about 7 kW to about 8 kW.

During operation 220, a carrier gas, for example, argon, nitrogen, helium, or a combination thereof, can be introduced to the active zone 172 of the plasma source interior 125 at a flow rate in a range from about 5,000 sccm to about 10,000 sccm, for example, from about 5,000 sccm to about 9,500 sccm, from about 5,500 to about 9,500 sccm, from about 5,500 sccm to about 8,500 sccm, from about 6,000 sccm to about 8,500 sccm, or from about 7,000 sccm to about 8,000 sccm. In some implementations, the carrier gas can be introduced for a period of time in a range from about 10 seconds(s) to about 500 s, for example, from about 60 s to about 400 s, from about 90 s to about 300 s, or from about 120 s to about 300 s. The carrier gas may facilitate flow of other process gases.

Not to be bound by theory but is believed that exposing the high-k dielectric material to the high density plasma nitridation process can (i) increase the crystallinity in the high-k film through its relatively high-temp temp (w/heater temp @400-600 C and/or relatively high temp plasma gas), (ii) further passivate oxygen vacancies due to high density nitrogen radicals and (iii) form a diffusion barriers against oxidant coming from subsequent deposition of High-k layers and thermal treatments, which eventually increases the k-value and further suppresses leakage current. In addition, the high-density plasma nitridation process performed at relatively high temperatures, for example, at 400° C. or greater can (iv) sufficiently increase crystallinity in the high-k dielectric material, eliminating the additional heat treatment steps previously used.

Optionally, at operation 230, the high-k dielectric layer 308 is exposed to a high density plasma oxidation process as shown in FIG. 3C. Exposure to the high density oxidation process during operation 230 can remove carbon impurities from the high-k dielectric layer 308 through chemical reaction between the carbon impurities and high-density oxygen radicals and passivate oxygen vacancies with the high-density oxygen radicals, which can eventually increase the k-value by increasing crystallinity in the high-k dielectric layer 308 and reduce the leakage current by removing traps. In some implementations, the high density plasma oxidation process can be performed by exposing the high-k dielectric layer 308 to a second radical, for example, an oxygen radical.

Referring to FIG. 1, when utilizing the plasma processing system 100 disclosed herein, a plasma including the second radical is formed in the active zone 172 of the plasma source interior 125. For example, the gas injection insert 140 can introduce a second process gas including oxygen to form the plasma including the second radical. The plasma can be an inductively coupled plasma generated within the gas injection channels 151 by the induction coil 130. The second process gas can be selected from H₂O, O₂, O₃, H₂O₂, NO₂, N₂O, or mixtures thereof. In some implementations, the second process gas can be introduced to the active zone 172 of the plasma source interior 125 at a second process gas flow rate in a range from about 1,000 standard cubic centimeters per minute (sccm) to about 10,000 sccm, for example, from about 1,000 sccm to about 9,500 sccm, from about 1,500 to about 9,500 sccm, from about 1,500 sccm to about 8,500 sccm, from about 4,000 sccm to about 8,500 sccm, or from about 6,000 sccm to about 8,000 sccm. In some implementations, the second radical can be introduced for a period of time in a range from about 10 seconds(s) to about 500 s, for example, from about 60 s to about 400 s, from about 90 s to about 300 s, or from about 120 s to about 300 s.

The plasma source 120 is configured to flow the plasma including the second radicals through the holes 126 in the separation grid 116 toward the substrate support 112 to treat the substrate 114 or the substrate stack 304 disposed thereon. The plasma source 120 may generate plasma charged particles, for example, ions and electrons, which recombine on the separation grid 116, so that mostly or only neutral plasma species can pass through the separation grid 116 and expose the substrate 114 or the substrate stack 304 to the high-density oxygen plasma. The plasma comprising the at least one oxygen radical species contacts a side of the high-k dielectric layer 308 facing the separation grid 116. The substrate 114 or the substrate stack 304 can be heating using the plurality of lamps 176 located on a second side of the substrate stack 304 opposite the separation grid 116.

The high-density oxygen plasma process of operation 230 may be formed while maintaining a pressure in a range from about 1 Torr to about 20 Torr, for example, from about 1 Torr to about 10 Torr, from about 1 Torr to about 8 Torr, or from about 1 Torr to about 5 Torr. In some implementations, the high-density oxygen plasma process of operation 230 is performed at a temperature which is less than the deposition temperature of the high-k dielectric layer 308 in order to prevent oxidation of the lower electrode 306. The high-density oxygen plasma process of operation 230 can be performed while maintaining a temperature in a range of 350° C. or less, for example, in a range from about 150° C. to about 350° C., for example, from about 150° C. to about 300° C., or from about 200° C. to about 300° C. In some implementations, the high-density oxygen plasma process of operation 230 can be performed while operating the plasma source at a power in a range from about 5 KW to about 10 KW, for example, from about 5 KW to about 8 KW, from about 6 KW to about 8 KW, or from about 7 KW to about 8 KW.

During operation 220, a carrier gas, for example, argon, nitrogen, helium, or a combination thereof, can be introduced to the active zone 172 of the plasma source interior 125 at a flow rate in a range from about 5,000 sccm to about 10,000 sccm, for example, from about 5,000 sccm to about 9,500 sccm, from about 5,500 to about 9,500 sccm, from about 5,500 sccm to about 8,500 sccm, from about 6,000 sccm to about 8,500 sccm, or from about 7,000 sccm to about 8,000 sccm. In some implementations, the carrier gas can be introduced for a period of time in a range from about 10 seconds(s) to about 500 s, for example, from about 60 s to about 400 s, from about 90 s to about 300 s, or from about 120 s to about 300 s. The carrier gas may facilitate flow of other process gases.

Not to be bound by theory but is believed that exposing the high-k dielectric material to the high density plasma oxidation process can (i) remove carbon impurities from the high-k dielectric material through chemical reaction between carbon and the high-density oxygen radicals; and (ii) passivate oxygen vacancies with high-density oxygen radicals, which can eventually increase the k-value by increasing crystallinity in the high-k dielectric material and reduce leakage current by removing traps. However, to prevent oxidation of the lower electrode, it needs to be applied below the high-k deposition temperature, for example, in a range from about 150° C. to about 350° C. or from about 250° C. to about 350° C.

In some implementations where operation 230 is not performed, after operation 220, the semiconductor device structure 300 may be exposed to additional processing to form the MIM capacitor structure. Additional processing can include, for example, at least one of the formation of additional high-k dielectric layers, additional electrode layers, and additional treatment processes. In some implementations where operation 230 is performed, after operation 230, the semiconductor device structure 300 may be exposed to additional processing to form the MIM capacitor structure.

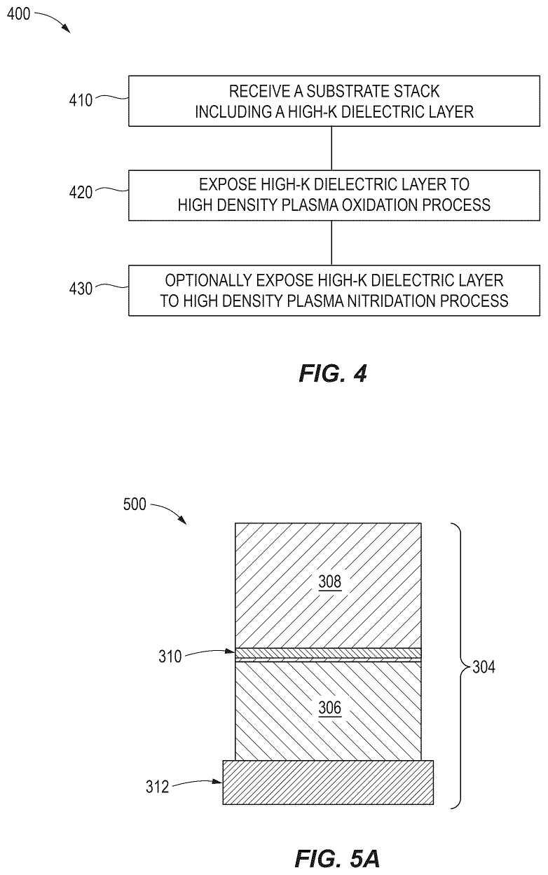

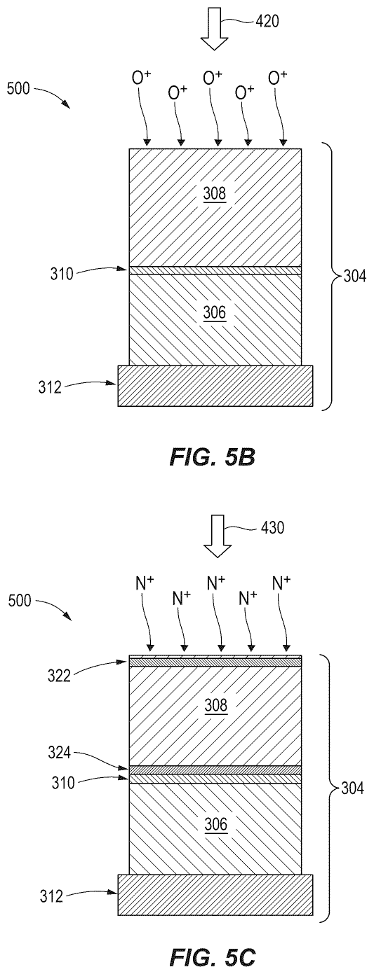

FIG. 4 is a flow diagram depicting a method 400 of treating a high-k dielectric layer in accordance with one or more implementations of the present disclosure. FIGS. 5A-5C illustrate views of various stages of forming a semiconductor structure in accordance with one or more implementations described herein. Although FIGS. 5A-5C are described in relation to the method 400, the structures disclosed in FIGS. 5A-5C are not limited to the method 400, but instead may stand alone as structures that are independent of the method 400. Similarly, although the method 400 is described in relation to FIGS. 5A-5C, the method 400 is not limited to the structures disclosed in FIGS. 5A-5C but instead may stand alone independent of the structures disclosed in FIGS. 5A-5C. It should be understood that FIGS. 5A-5C illustrate only partial schematic views of a semiconductor device structure 500, and the semiconductor device structure 500 may contain any number of transistor sections and additional materials having aspects as illustrated in the figures. The semiconductor device structure 500 can be a MIM capacitor. It should also be noted that although the method 400 illustrated in FIG. 4 is described sequentially, other process sequences that include one or more operations that have been omitted and/or added, and/or has been rearranged in another desirable order, fall within the scope of the implementations of the disclosure provided herein.

The method 400 is similar to the method 200 except that the high density plasma oxidation process is performed prior to the high density plasma nitridation process.

At operation 410 a substrate stack 304 is received. The substrate stack 304 may be positioned on the substrate support 112 of the plasma processing system 100 shown in FIG. 1. At operation 420, the high-k dielectric layer 308 is exposed to a high density plasma oxidation process as shown in FIG. 5B. Operation 420 may be performed similarly to operation 230. At operation 430, the high-k dielectric layer 308 is exposed to a high density plasma nitridation process as shown in FIG. 5C. Operation 430 may be performed similarly to operation 220.

After operation 430, the semiconductor device structure 500 may be exposed to additional processing to form the MIM capacitor structure. Additional processing can include, for example, at least one of the formation of additional high-k dielectric layers, additional electrode layers, and additional treatment processes.

Not to be bound by theory but is believed that the dual treatment of plasma oxidation (PO) followed by plasma nitridation (PN) on a high-k layer can further increase the crystallinity in high-k and further reduce leakage current compared to plasma nitridation alone. Applying plasma oxidation can (i) remove carbon impurities from the high-k dielectric layer 308 through chemical reaction between carbon and the high-density oxygen radicals and (ii) passivate oxygen vacancies with high-density oxygen radicals, which can eventually increase the k-value by increasing the crystallinity of the high-k dielectric layer 308 and reduce its leakage current by removing traps. However, to prevent oxidation of the lower electrode, it needs to be applied below the high-k deposition temperature, for example, at a temperature in a range from about 150° C. to about 350° C. Subsequent plasma nitridation can (i) increase the crystallinity in the high-k dielectric layer 308 film through its relatively high-temp temp (w/heater temp @400-600 C and/or relatively high temp plasma gas), (ii) further passivate oxygen vacancies due to high density nitrogen radicals and (iii) form a diffusion barriers against oxidant coming from subsequent deposition of additional high-k dielectric layers and/or thermal treatments, which eventually increases the k-value and further suppresses leakage current. In addition, plasma nitridation at relatively high temperatures, for example, 350° C. or greater, can (iv) sufficiently increase crystallinity in the HK, eliminating the additional heat treatment steps previously used.

The previously described implementations of the present disclosure have many advantages. However, the present disclosure does not necessitate that all the advantageous features and all the advantages need to be incorporated into every implementation of the present disclosure. A high-density plasma treatment process, which reduces leakage current and increases capacitance in MIM capacitors. The removal of oxygen vacancies in high-k layers, prevention of an increase in the interfacial layer thickness through the formation of nitric layers between high-k layers and electrodes, the formation of barriers to prevent inter-diffusion of impurities from high-k layers and electrodes, and the enhancement of crystallinity in high-k without the post-deposition anneal, which is currently performed.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A plasma processing method, comprising:
receiving a substrate stack into a processing chamber, the substrate stack comprising a high-k dielectric layer formed over a metal electrode;
introducing a process gas into a gas injection channel defined between a gas injection insert and a sidewall of a plasma source;
generating an inductively coupled plasma within the gas injection channel with an induction coil positioned proximate the sidewall and horizontally overlapping the gas injection channel, wherein the plasma comprises at least one nitrogen radical species;
delivering the plasma from the plasma source to the processing chamber coupled therewith, wherein the plasma flows through a separation grid disposed between the plasma source and the substrate stack to be processed; and
processing the substrate stack within the processing chamber, wherein processing the substrate stack comprises:
contacting the plasma comprising the at least one nitrogen radical species with the high-k dielectric layer facing the separation grid; and
heating the substrate stack using a plurality of lamps located on a second side of the substrate stack opposite the separation grid.

2. The method of claim 1, wherein after processing the substrate stack with the plasma, the method further comprises:
introducing an oxygen-containing gas into the gas injection channel of the plasma source;
generating an oxygen plasma within the gas injection channel, wherein the oxygen plasma includes oxygen radicals;
delivering the oxygen plasma from the plasma source to the processing chamber; and
processing the substrate stack with the oxygen plasma within the processing chamber, wherein processing the substrate stack comprises:
contacting the oxygen plasma comprising the oxygen radicals with the high-k dielectric layer facing the separation grid; and
heating the substrate stack using the plurality of lamps located on the second side of the substrate stack opposite the separation grid.

3. The method of claim 1, wherein processing the substrate stack within the processing chamber forms one or more nitrogen-containing diffusion barrier layers within the substrate stack.

4. The method of claim 3, wherein a diffusion barrier layer of the one or more diffusion barrier layers is formed within the high-k dielectric layer.

5. The method of claim 3, wherein a diffusion barrier layer of the one or more diffusion barrier layer is formed at an interface of the high-k dielectric layer and the metal electrode.

6. The method of claim 1, wherein the high-k dielectric layer comprises zirconium oxide, hafnium oxide, or a combination of zirconium oxide and hafnium oxide.

7. The method of claim 6, wherein the metal electrode comprises a metal nitride with the metal selected from titanium (Ti), molybdenum (Mo), tungsten (W), or tantalum (Ta).

8. The method of claim 1, wherein the high-k dielectric layer is formed by an atomic layer deposition (ALD) process.

9. A plasma processing method, comprising:
receiving a substrate stack into a processing chamber, the substrate stack comprising a high-k dielectric layer formed over a metal electrode;
introducing a process gas into a gas injection channel defined between a gas injection insert and a sidewall of a plasma source;
generating an inductively coupled plasma within the gas injection channel with an induction coil positioned proximate the sidewall and horizontally overlapping the gas injection channel, wherein the plasma comprises at least one oxygen radical species;
delivering the plasma from the plasma source to the processing chamber coupled therewith, wherein the plasma flows through a separation grid disposed between the plasma source and the substrate stack to be processed; and
processing the substrate stack within the processing chamber, wherein processing the substrate stack comprises:
contacting the plasma comprising the at least one oxygen radical species with the high-k dielectric layer facing the separation grid; and
heating the substrate stack using a plurality of lamps located on a second side of the substrate stack opposite the separation grid.

10. The method of claim 9, wherein after processing the substrate stack with the plasma, the method further comprises:
introducing a nitrogen-containing gas into the gas injection channel of the plasma source;
generating a nitrogen plasma within the gas injection channel, wherein the nitrogen plasma includes nitrogen radicals;
delivering the nitrogen plasma from the plasma source to the processing chamber; and
processing the substrate stack with the nitrogen plasma within the processing chamber, wherein processing the substrate stack comprises:
contacting the nitrogen plasma comprising the nitrogen radicals with the high-k dielectric layer facing the separation grid; and
heating the substrate stack using the plurality of lamps located on the second side of the substrate stack opposite the separation grid.

11. The method of claim 10, wherein processing the substrate stack with the nitrogen plasma forms one or more nitrogen-containing diffusion barrier layers within the substrate stack.

12. The method of claim 11, wherein a diffusion barrier layer of the one or more diffusion barrier layers is formed within the high-k dielectric layer.

13. The method of claim 11, wherein a diffusion barrier layer of the one or more diffusion barrier layer is formed at an interface of the high-k dielectric layer and the metal electrode.

14. The method of claim 9, wherein the high-k dielectric layer comprises zirconium oxide, hafnium oxide, or a combination of zirconium oxide and hafnium oxide.

15. The method of claim 14, wherein the metal electrode comprises a metal nitride with the metal selected from titanium (Ti), molybdenum (Mo), tungsten (W), or tantalum (Ta).

16. The method of claim 9, wherein the high-k dielectric layer is formed by an atomic layer deposition (ALD) process.

17. A plasma processing system, comprising:
a processing chamber defining a processing volume; and
a plasma source;
a gas injection insert disposed within the plasma source;
a gas injection channel defined between the gas injection insert and a sidewall of the plasma source;
an induction coil positioned proximate to the sidewall and horizontally overlapping the gas injection channel;
a separation grid that separates the plasma source from the processing volume; and
a system controller, comprising:
a memory for storing computer readable instructions; and
a processor coupled to the memory, the processor configured by the computer readable instructions that when executed by the processor perform a plurality of operations comprising:
introducing a process gas into the gas injection channel;
generating an inductively coupled plasma within the gas injection channel with the induction coil, wherein the plasma comprises at least one nitrogen radical species
delivering the plasma from the plasma source to the processing volume, wherein the plasma flows through the separation grid; and
processing a substrate stack within the processing volume, the substrate stack comprising a high-k dielectric layer formed over a metal electrode, wherein processing the substrate stack comprises:
contacting the plasma comprising the at least one nitrogen radical species with the high-k dielectric layer facing the separation grid; and
heating the substrate stack using a plurality of lamps located on a second side of the substrate stack opposite the separation grid.

18. The system of claim 17, wherein after processing the substrate stack with the plasma, the plurality of operations further comprise:
introducing an oxygen-containing gas into the gas injection channel of the plasma source;
generating an oxygen plasma within the gas injection channel, wherein the oxygen plasma includes oxygen radicals;
delivering the oxygen plasma from the plasma source to the processing volume; and
processing the substrate stack with the oxygen plasma within the processing volume, wherein processing the substrate stack comprises:
contacting the oxygen plasma comprising the oxygen radicals with the high-k dielectric layer facing the separation grid; and
heating the substrate stack using the plurality of lamps located on the second side of the substrate stack opposite the separation grid.

19. The system of claim 17, wherein processing the substrate stack within the processing volume forms one or more nitrogen-containing diffusion barrier layers within the substrate stack.

20. The system of claim 17, wherein the high-k dielectric layer comprises zirconium oxide, hafnium oxide, or a combination of zirconium oxide and hafnium oxide and the metal electrode comprises a metal nitride with the metal selected from titanium (Ti), molybdenum (Mo), tungsten (W), or tantalum (Ta).
